(19) United States
(12) Patent Application Publication
(10) Pub. No.: US 2019/0281711 A1
(43) Pub. Date: Sep. 12, 2019

(54) SYSTEMS AND METHODS FOR ACCELERATED TEMPERATURE ACCLIMATION OF EQUIPMENT

(71) Applicant: Dell Products L.P., Round Rock, TX (US)

(72) Inventors: Austin M. SHELNUTT, Leander, TX (US); Steven EMBLETON, Austin, TX (US); Rene J. SALAS, Round Rock, TX (US); Eric M. TUNKS, Austin, TX (US)

(73) Assignee: Dell Products L.P., Round Rock, TX (US)

(21) Appl. No.: 15/914,851

(22) Filed: Mar. 7, 2018

(51) Int. Cl. H05K 5/02; H05K 7/20

(52) U.S. Cl. CPC H05K 5/0213; H05K 7/20127; H05K 7/20181

(57) ABSTRACT

In accordance with embodiments of the present disclosure, an apparatus may include an enclosure comprising a material impermeable to fluids, an ingress vent integral to the enclosure and including a desiccant, and an egress vent integral to the enclosure. The ingress vent and egress vent may be configured such that, through natural convection of air, air ingresses from an exterior of the enclosure to an interior of the enclosure via the ingress vent and is dehumidified by the desiccant during ingress, such air after dehumidification thermally interacts with a physical item enclosed in the interior of the enclosure such that a temperature of the physical item increases and a temperature of the air decreases, and such air after cooling egresses from the interior to the exterior via the egress vent.

### TECHNICAL FIELD

The present disclosure relates in general to information handling systems, and more particularly to accelerated temperature acclimation of an information handling system or other equipment to an ambient temperature.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems are often implemented using racks. A rack may comprise a standardized frame or enclosure for mounting multiple electronic equipment modules, such as server computing nodes, computer-readable storage media, telecommunications equipment, broadcasting equipment, audio equipment, scientific lab equipment, or sleds of other information handling resources. Racks are often shipped via ground transportation (e.g., via semi-tractor trailer) or air transportation (e.g., in a cargo hold in an aircraft) between a source facility (e.g., manufacturing facility, warehouse, shipping port, shipping hub, etc.) and a destination facility (e.g., data center of an enterprise purchasing the information handling system). When shipped, especially during periods of cooler outdoor temperatures, a rack may be exposed to extreme cold temperatures. In some instances, outdoor winter temperatures to which the rack may be exposed during shipment may be significantly below the dew point temperature of a destination facility, which can lead to condensation of liquid (e.g., water) or deposition of solid (e.g. frost) on the rack and its electronic components. Such condensation or deposition can cause catastrophic damage to the electronic components.

Existing solutions to protecting racks of electronic equipment from spontaneous condensation when delivered to a destination facility include packing racks in plastic bags, thus preventing rapid exposure to the air of the destination facility, which may be hot and/or humid. However, such solutions are less than desirable, as a rack may still require many hours to acclimate to a temperature at which the rack can be removed from the plastic bag and exposed to the ambient temperature of the destination facility.

### SUMMARY

In accordance with the teachings of the present disclosure, one or more disadvantages and problems associated with temperature acclimation of equipment to an ambient temperature may be reduced or eliminated.

In accordance with embodiments of the present disclosure, an apparatus may include an enclosure comprising a material impermeable to fluids, an ingress vent integral to the enclosure and including a desiccant, and an egress vent integral to the enclosure. The ingress vent and egress vent may be configured such that, through natural convection of air, air ingresses from an exterior of the enclosure to an interior of the enclosure via the ingress vent and is dehumidified by the desiccant during ingress, such air after dehumidification thermally interacts with a physical item enclosed in the interior of the enclosure such that a temperature of the physical item increases and a temperature of the air decreases, and such air after cooling egresses from the interior to the exterior via the egress vent.

In accordance with these and other embodiments of the present disclosure, a method comprising may include forming an ingress vent integral to an enclosure comprising a material impermeable to fluids, the ingress vent including a desiccant, forming an egress vent integral to the enclosure, and configuring the ingress vent and the egress vent such that, through natural convection of air, air ingresses from an exterior of the enclosure to an interior of the enclosure via the ingress vent and is dehumidified by the desiccant during ingress, such air after dehumidification thermally interacts with a physical item enclosed in the interior of the enclosure such that a temperature of the physical item increases and a temperature of the air decreases, and such air after cooling egresses from the interior to the exterior via the egress vent.

In accordance with these and other embodiments of the present disclosure, a method may include causing air, through natural convection, to ingress from an exterior of an enclosure comprising a material impermeable to fluids via an ingress vent integral to an enclosure, the ingress vent including a desiccant. The method may also include dehumidifying the air with the desiccant. The method may further include causing the air, after dehumidification, to thermally interact with a physical item enclosed in the interior of the enclosure such that a temperature of the physical item increases and a temperature of the air decreases. The method may additionally include causing the air, through natural convection, to egress from an interior of the enclosure to the exterior via an egress vent integral to the disclosure.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of a side elevation view of an example system for accelerated temperature acclimation of equipment, in accordance with embodiments of the present disclosure; and

FIGS. 2A-2C show various views of an example desiccant vent for use in the system illustrated in FIG. 1, in accordance with embodiments of the present disclosure.

### DETAILED DESCRIPTION

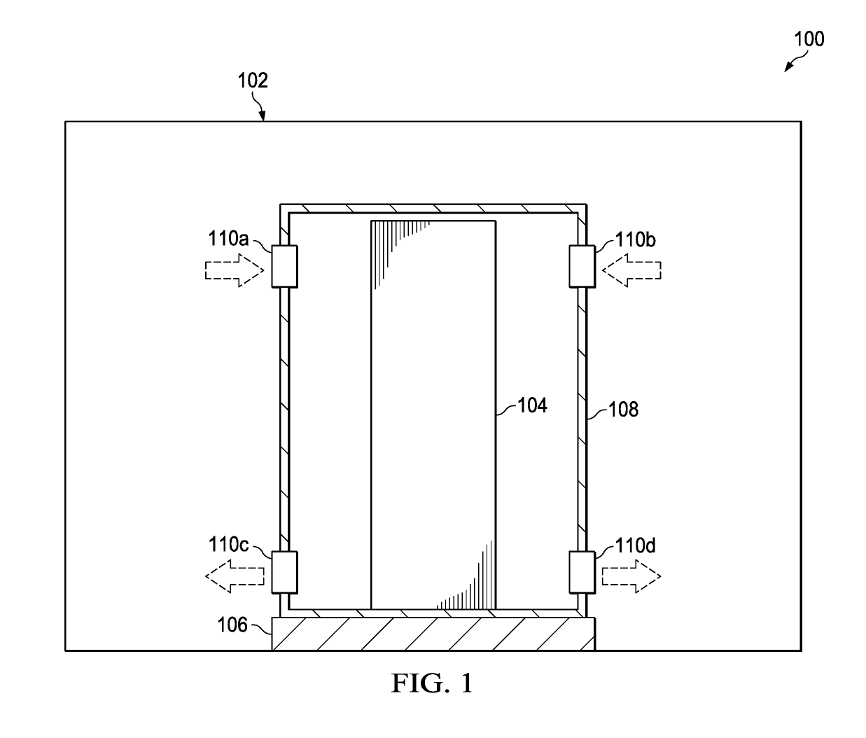

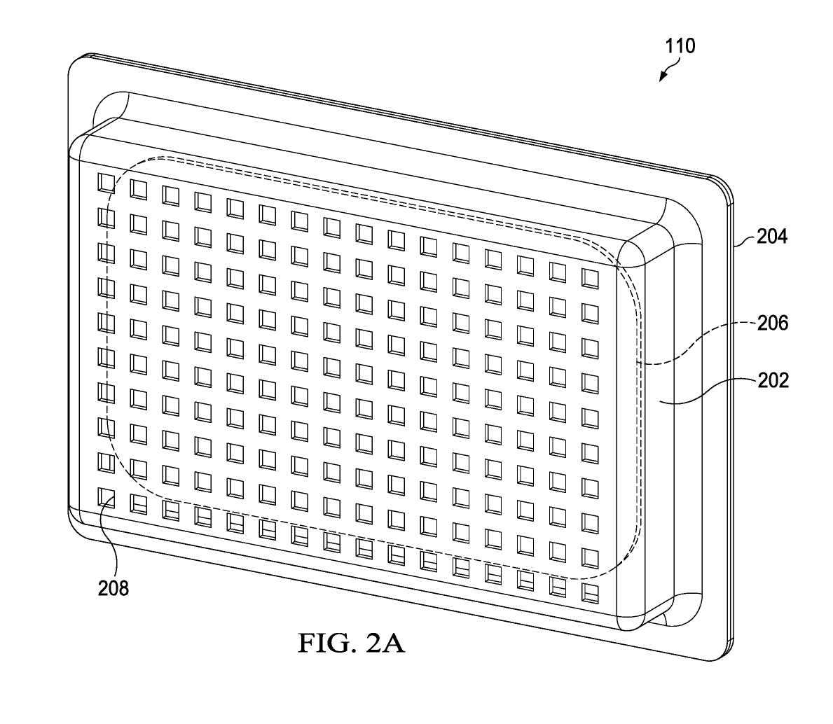

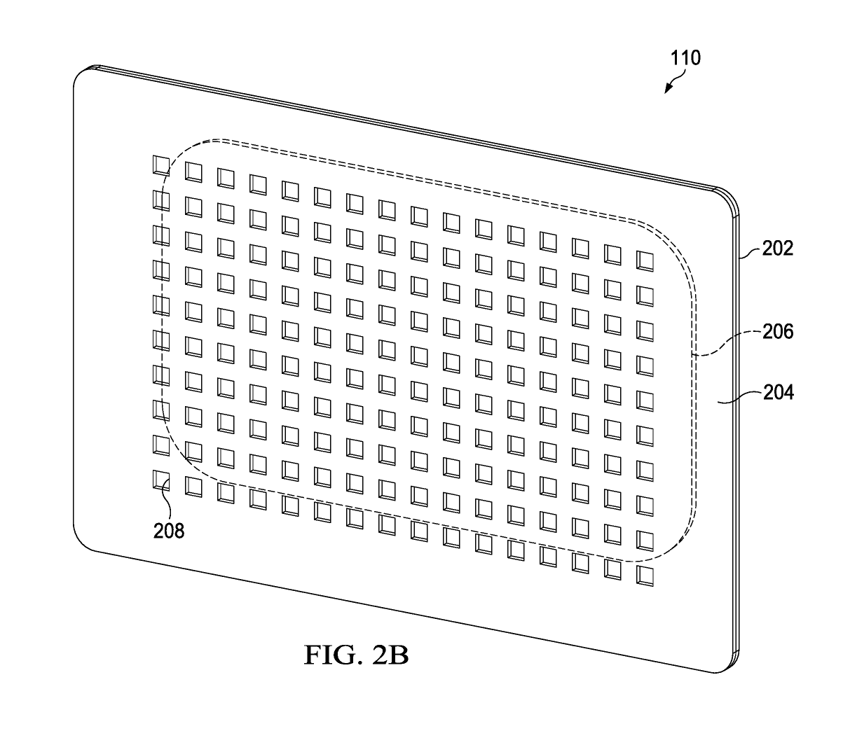

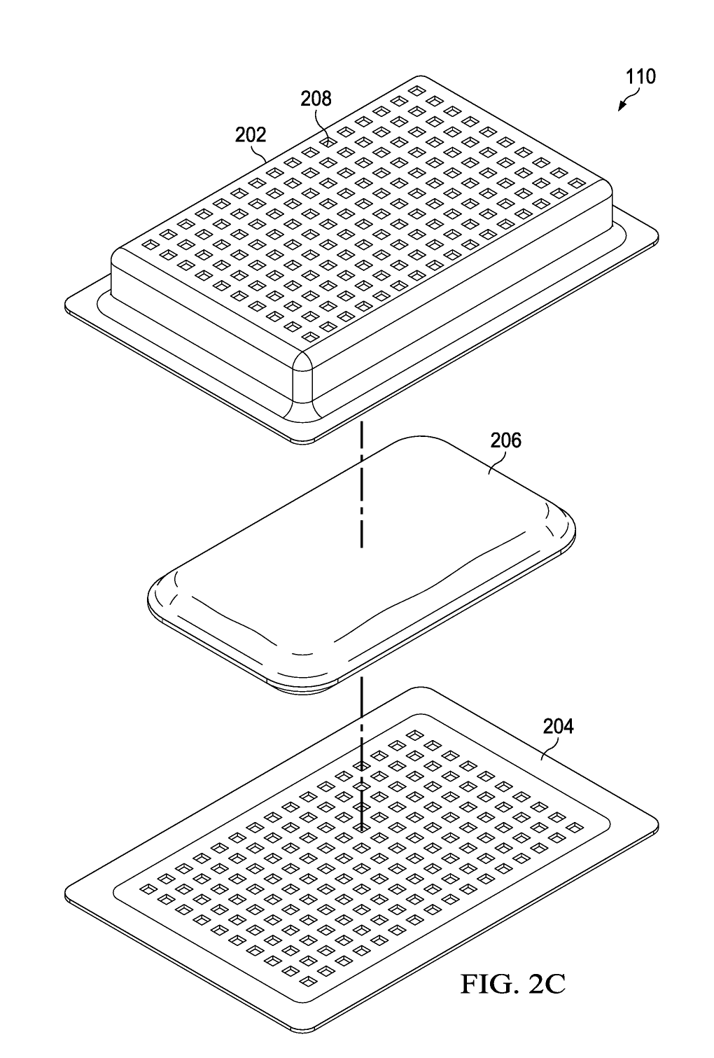

Preferred embodiments and their advantages are best understood by reference to FIGS. 1 through 2C, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

FIG. 1 illustrates a block diagram of a side elevation view of an example system 100 for accelerated temperature acclimation of equipment 104, in accordance with embodiments of the present disclosure. As shown in FIG. 1, system 100 may include an ambient environment 102 and equipment 104 placed or mounted on a pallet 106 and placed within an enclosure 108 having a plurality of integrated desiccant vents 110 (e.g., desiccant vents 110a, 110b, 110c, and 110d). A desiccant vent 110a, 110b, 110c, and 110d may be referred to herein individually as a desiccant vent 110 and two or more desiccant vents 110a, 110b, 100c, and 110d may be referred to herein collectively as desiccant vents 110.

Ambient environment 102 may include any suitable environment into which equipment 104 may be located. In some embodiments, ambient environment 102 may include an interior room of a building, such as a data center room or a room adjacent to a delivery receiving dock.

Equipment 104 may comprise any physical item for which it is desired to avoid liquid condensation or solid deposition on such physical item. In some embodiments, equipment 104 may comprise an information handling system, such as a rack. In other embodiments, equipment 104 may comprise electronic components. In yet other embodiments, equipment 104 may include a physical item free from electronics but for which condensation of liquid or deposition of a solid may be undesirable, such as a collectible, a piece of art, an archeological relic, or other valuable.

Pallet 106 may comprise any suitable transport structure that supports goods in a stable fashion while being lifted by a forklift, pallet jack, front loader, work saver, other jacking device, or a crane. Equipment 104 may be secured on pallet 106 with strapping, stretch wrap, shrink wrap, and/or other suitable mechanical features. Pallet 106 may be made of wood, plastic, metal, and/or other suitable material.

Enclosure 108 may comprise any suitable sealed cover that (aside from the passage of air through desiccant vents 110 as described below) creates a physical barrier to the passage of fluids (e.g., air and/or liquid) through the enclosure 108. In some embodiments, enclosure 108 may comprise plastic material (e.g., polyethylene) such as a plastic bag for example. As shown in FIG. 1, enclosure 108 may include a plurality of integrated desiccant vents 110. In some embodiments, enclosure 108 may enclose both equipment 104 and pallet 106. In other embodiments, enclosure 108 may enclose equipment 104 but not pallet 106. In yet other embodiments, equipment 104 may be transported without pallet 106 or by a means other than pallet 106.

A desiccant vent 110 may be any suitable vent configured to allow the passage of air through the vent, the vent comprising a chemical desiccant for absorbing moisture (e.g., water vapor or other liquid vapor) from air passing through the vent, so as to reduce humidity of such air as it passes through desiccant vent 110. FIGS. 2A-2C provide detailed illustration of an example desiccant vent 110.

FIGS. 2A-2C show various views of an example desiccant vent 110 for use with enclosure 108 in the system illustrated in FIG. 1, in accordance with embodiments of the present disclosure. FIG. 2A illustrates a front assembled view of desiccant vent 110, FIG. 2B illustrates a rear assembled view of desiccant vent 110, and FIG. 2C illustrates an exploded view of desiccant vent 110. Applicant notes that the terms “front” and “rear” are used only for purposes of illustration and exposition, and the use of terms is not intended to limit a configuration of desiccant vent 110 relative to enclosure 108 and/or limit a direction of air flow through desiccant vent 108. In other words, a desiccant vent 110 may be configured relative to enclosure 108 such that the “front” of desiccant vent 110 is external to enclosure 108 and the “rear” of desiccant vent is internal to enclosure 108, or may be configured relative to enclosure 108 such that the “rear” of desiccant vent 110 is external to enclosure 108 and the “front” of desiccant vent 110 is internal to enclosure 108. Furthermore, air may flow through desiccant vent 110 either from the “front” to the “rear” or from the “rear” to the “front.”

As shown in FIGS. 2A-2C, desiccant vent 110 may include an assembly comprising a first member 202 and second member 204, and a desiccant 206. As depicted in FIGS. 2A-2C, first member 202 and second member 204 may be mechanically coupled together (e.g., by screws or other fasteners, by adhesives, by mechanical features on each of the first member 202 and second member 204, etc.) to form an enclosure in which desiccant 206 may reside. As assembled, air may pass through vent holes 208 formed on one of first member 202 and second member 204, then through desiccant 206, then through vent holes 208 formed on the other of first member 202 and second member 204. Each of first member 202 and second member 204 may be formed using any suitable material, including without limitation hard plastic, metal, or other material.

Desiccant 206 may comprise any suitable hygroscopic substance that induces or sustains a state of dryness (i.e., desiccation) in its vicinity. In some embodiments, desiccant 206 may comprise such hygroscopic material contained within a bag, pouch, or other cover that is permeable to air, allowing air to pass through such cover and the hygroscopic material to reduce the humidity of the air. The hygroscopic substance of desiccant 206 may comprise silica, charcoal, calcium sulfate, calcium chloride, and/or another suitable hygroscopic material.

In operation, in order to accelerate temperature acclimation of equipment 104 to an ambient temperature of ambient environment 102, currents generated by natural convection of air may cause air to ingress into enclosure 108 via one or more desiccant vents 110a and 110b. Desiccant 206 of such ingress desiccant vents 110a and 110b may reduce the humidity of the ingressing air. Such dehumidified ingressing air may then thermally interact with equipment 104 to increase the temperature of equipment 104 while decreasing the temperature of the dehumidified ingressing air. Because natural convection heat transfer is buoyancy (density gradient) driven, fluid motion of air may be parallel to the force of gravity (e.g., from ingress desiccant vents 110a and 110b to egress desiccant vents 110c and 110d). Accordingly, after air is cooled via its thermal interaction with equipment 104, such air may egress via egress desiccant vents 110c and 110d to the outside of enclosure 108.

As described above, desiccant vents 110 may be integral to enclosure 108. In some embodiments, desiccant vents 110 may be disposable. In other embodiments, desiccant vents 110 may be reused by opening the assembly formed by first member 202 and second member 204, replacing desiccant 206 with new desiccant 206, and closing the assembly.

Furthermore, the amount of moisture that can be absorbed by a chemical desiccant is finite and proportionate to the mass of the desiccant. Thus, circumstances where an ambient dew point of ambient environment 102 is significantly high relative to that of equipment 104, one or more of desiccant vents 110 may include a cover for controlling an amount of air that can pass through desiccant vent 110. For example, in some embodiments, such cover may include a slidable cover that slides relative to one of first member 202 and second member 204 and allows a user to control a number of vent holes 208 exposed for passage of air. As another example, in some embodiments such cover may comprise an adhesive decal affixed to one of first member 202 and second member 204 and of which a user can peel a desired amount of the adhesive decal from the first member 202/second member 204 to control a number of vent holes 208 exposed for passage of air. In these and other embodiments, such cover may also serve to prevent passage of air through a desiccant vent 110 while equipment 104 is being shipped in enclosure 108, and such cover may be completely or partially removed after delivery to allow for temperature acclimation through natural convection of dehumidified air, as described herein.

Thus, at a source facility for shipping of equipment 104, equipment 104 may be enclosed within enclosure 108 and shipped to its destination facility. Then, once at the destination facility, desiccant vents 110 may be used to facilitate temperature acclimation of equipment 104 to ambient environment 102 using natural convection of air, as described herein.

Although FIG. 1 depicts enclosure 108 having two ingress desiccant vents 110a, 110b and two egress desiccant vents 110c, 110d, enclosure 108 may comprise any suitable number of ingress desiccant vents 110 and any suitable number of egress desiccant vents 110. Further, enclosure 108 may comprise a number of ingress desiccant vents 110 that is not equal to the number of egress desiccant vents 110.

In addition, in some embodiments, in lieu of egress desiccant vents 110, enclosure 108 may include egress vents which are not configured or adapted for holding desiccant 206 and may simply pass air from the interior of enclosure 108 to the exterior of enclosure 108.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

1. An apparatus comprising:
an enclosure;
at least one ingress vent integral to the enclosure and including a desiccant, wherein the at least one ingress vent includes a cover for controlling an amount of airflow permitted to pass through the at least one ingress vent, and wherein the cover includes either a slidable cover capable of being partially opened or an adhesive cover capable of being partially peeled back; and
at least one egress vent integral to the enclosure;
wherein the at least one ingress vent and the at least one egress vent are configured such that, through natural convection of air:
air ingresses from an exterior of the enclosure to an interior of the enclosure via the at least one ingress vent and is dehumidified by the desiccant during ingress;
such air after dehumidification thermally interacts with a physical item enclosed in the interior of the enclosure such that a temperature of the physical item increases and a temperature of the air decreases; and
such air after cooling egresses from the interior to the exterior via the at least one egress vent; and
wherein the enclosure is sealed to prevent passage of air between the exterior and the interior except for air passing through the at least one ingress vent and the at least one egress vent.

2. The apparatus of claim 1, wherein the at least one egress vent includes a second desiccant.

3. The apparatus of claim 1, wherein the enclosure is a plastic bag.

4. The apparatus of claim 1, wherein the physical item comprises electronic components.

5. (canceled)

6. The apparatus of claim 1, wherein the at least one ingress vent is configured to be reusable by replacing the desiccant.

7. (canceled)

8. A method comprising:
forming at least one ingress vent integral to an enclosure, the at least one ingress vent including a desiccant;
coupling a cover to the at least one ingress vent for controlling an amount of airflow permitted to pass through the at least one ingress vent, wherein the cover includes either a slidable cover capable of being partially opened or an adhesive cover capable of being partially peeled back;
forming at least one egress vent integral to the enclosure;
configuring the at least one ingress vent and the at least one egress vent such that, through natural convection of air:
air ingresses from an exterior of the enclosure to an interior of the enclosure via the at least one ingress vent and is dehumidified by the desiccant during ingress;
such air after dehumidification thermally interacts with a physical item enclosed in the interior of the enclosure such that a temperature of the physical item increases and a temperature of the air decreases; and
such air after cooling egresses from the interior to the exterior via the at least one egress vent; and
sealing the enclosure to prevent passage of air between the exterior and the interior except for air passing through the at least one ingress vent and the at least one egress vent.

9. The method of claim 8, wherein the at least one egress vent includes a second desiccant.

10. The method of claim 8, wherein the enclosure is a plastic bag.

11. The method of claim 8, wherein the physical item comprises electronic components.

12. (canceled)

13. The method of claim 8, further comprising configuring the at least one ingress vent to be reusable by replacing the desiccant.

14. (canceled)

15. A method comprising:
causing air, through natural convection, to ingress from an exterior to an interior of an enclosure via at least one ingress vent integral to the enclosure, the at least one ingress vent including a desiccant;
manipulating a cover to the at least one ingress vent to control an amount of airflow permitted to pass through the at least one ingress vent, wherein the cover includes either a slidable cover capable of being partially opened or an adhesive cover capable of being partially peeled back;
dehumidifying the air with the desiccant;
causing the air, after dehumidification, to thermally interact with a physical item enclosed in the interior of the enclosure such that a temperature of the physical item increases and a temperature of the air decreases; and
causing the air, through natural convection, to egress from the interior of the enclosure to the exterior via at least one egress vent integral to the enclosure;
wherein the enclosure is sealed to prevent passage of air between the exterior and the interior except for air passing through the at least one ingress vent and the at least one egress vent.

16. The method of claim 15, wherein the at least one egress vent includes a second desiccant.

17. The method of claim 15, wherein the enclosure is a plastic bag.

18. The method of claim 15, wherein the physical item comprises electronic components.

19. (canceled)

20. The method of claim 15, further comprising replacing the desiccant.

21. (canceled)
